(19) United States
(12) Patent Application Publication
(10) Pub. No.: US 2010/0023817 A1
(43) Pub. Date: Jan. 28, 2010

(54) TEST SYSTEM AND METHOD

(75) Inventors: Jae-Woo PARK, Suwon-si (KR); Jae-Yong JEONG, Yongin-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/499,977

(22) Filed: Jul. 9, 2009

(30) Foreign Application Priority Data
Jul. 25, 2008 (KR) 10-2008-73092

(51) Int. Cl. G11C 29/04; G06F 11/22

(52) U.S. Cl. 714/718; 714/E11.145

(57) ABSTRACT

A test system includes a memory device having a data I/O circuit connected to a data write-in path and a data read-out path. During test mode, the data I/O circuit retains a copy of test pattern data received in the I/O circuit via the data write-in path as output test data before the test pattern data is stored in a memory cell array as write data. The test system also includes a test device generating the test pattern data, receiving the output test data from the memory device, comparing the output test data with the test pattern data, and generating an error detection signal on the basis of the comparison. The error detection signal indicates the presence or absence of a defect in the data write-in or read-out path.

### CROSS-REFERENCE TO RELATED APPLICATION

This U.S. non-provisional patent application claims priority under 35 U.S.C. §119 to Korean Patent Application No. 10-2008-73092 filed on Jul. 25, 2008, the subject matter of which is hereby incorporated by reference.

### BACKGROUND

The present invention relates to semiconductor memory devices and more particularly, to a test system and method for a semiconductor memory devices.

Semiconductor memory devices may be generally classified into volatile and nonvolatile types. Volatile memories operate at relatively high data access speeds, but lose stored data when power is interrupted. Volatile memories include, for example, static ransom access memory (RAM), dynamic RAM (DRAM), and synchronous DRAM (SDRAM).

In contrast, nonvolatile memories retain stored data even power is interrupted. Thus, the nonvolatile memory devices have been widely adopted for use in applications demanding data retention in the absence of applied power. There are many kinds of nonvolatile memories including, for example, mask read-only memory (MROM), programmable ROM (PROM), erasable and programmable ROM (EPROM), electrically erasable and programmable ROM (EEPROM), flash memory, phase-change RAM (PRAM), magnetic RAM (MRAM), resistive RAM (RRAM), and ferroelectric RAM (FRAM).

Flash memory is nonvolatile and enjoys many advantages in operation and manufacture. As a result, flash memory has been widely employed in computers and memory cards because of its ability to be readily (electrically) erased while providing nonvolatile data storage in a densely integrated memory device.

Flash memory as conventionally provided includes NOR and NAND types, as distinguished by the interconnection pattern between constituent memory cells and bit lines. NOR-type flash memory has a structure in which a single bit line is connected in parallel with two or more cell transistors. In NOR-type flash memory, data is stored by an electrical phenomenon commonly referred to as hot electron injection, but is erased by a separate phenomenon referred to as Fowler-Nordheim (F-N) tunneling. In NAND-type flash memory, a bit line is series connected to two or more cell transistors and data is both stored and erased using F-N tunneling.

NOR flash memory is disadvantageous in its relatively low integration density and relatively high current consumption. However, NOR flash memory is capable of operating at relatively high frequencies. In contrast, NAND flash memory is advantageous in its relatively high integration density and low current consumption.

### SUMMARY

Embodiments of the present invention are directed to a test system and method capable of rapidly detecting a defect in a data path in a memory device.

In one embodiment, the invention provides a test system comprising; a memory device having a data input/output (I/O) circuit configured to connect a data write-in path used to write data to a memory cell array and a data read-out path used to read data from the memory cell array, and further configured during a test mode to retain a copy of test pattern data received in the I/O circuit via the data write-in path as output test data before the test pattern data is stored in the memory cell array as write data, and a test device configured during the test mode to generate the test pattern data, receive the output test data from the memory device, compare the output test data with the test pattern data, and generate an error detection signal on the basis of the comparison of the output test data and the test data pattern, wherein the error detection signal indicates the presence or absence of a defect in the data write-in or read-out path.

In another embodiment, the invention provides a test method for a memory device having a memory cell array, the method comprising; generating test pattern data in a test device connected to the memory device, applying the test pattern data to the memory device via a data write-in path, converting the test pattern data into output test data and latching the output test data in an input/output (I/O) circuit of the memory device before writing the test pattern data to the memory cell array, providing the output test data via a data read-out path of the memory device, and comparing the output test data with the test pattern data to identify the presence or absence of a defect in the data write-in path or the data read-out path.

### BRIEF DESCRIPTION OF THE FIGURES

Non-limiting and non-exhaustive embodiments of the invention will be described with reference to the following figures, wherein like reference numbers and labels refer to like or similar elements unless otherwise specified. In the figures:

FIG. 1 is a block diagram of a test system according to an embodiment of the invention;

FIG. 2 is a partial circuit diagram of the memory cell array shown in FIG. 1;

FIG. 3 is a block diagram of the data I/O (I/O) circuit shown in FIG. 1; and

FIG. 4 is a flow chart summarizing a test method for a memory device in accordance with an embodiment of the invention.

### DESCRIPTION OF EMBODIMENTS

Embodiments of the invention will now be described in some additional detail with reference to the accompanying drawings. The present invention may, however, be embodied in different forms and should not be constructed as being limited to only the illustrated embodiments. Rather, these embodiments are presented as teaching examples.

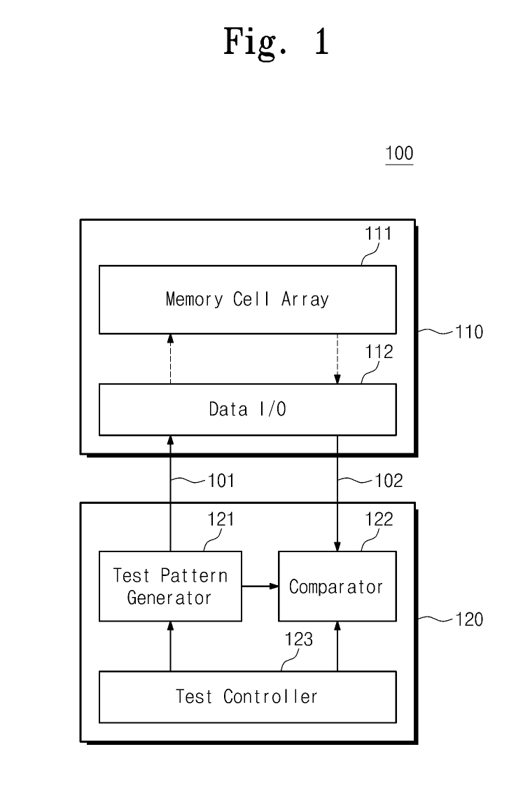

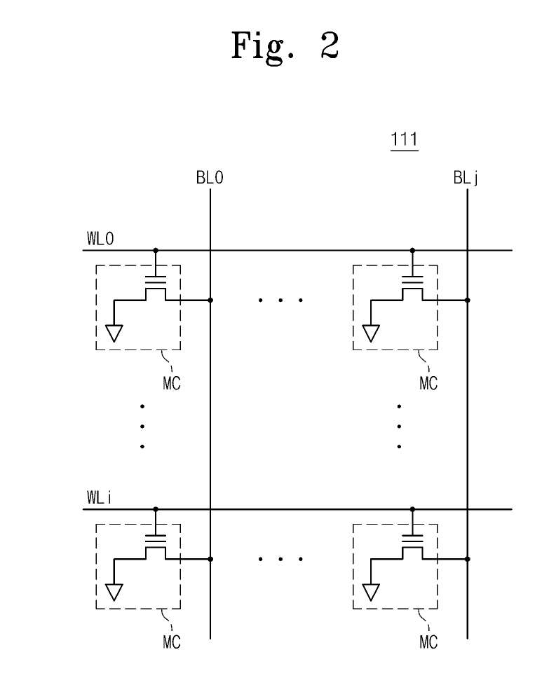

FIG. 1 is a block diagram of a test system 100 according to an embodiment of the invention. FIG. 2 is a partial circuit diagram of the memory cell array 111 shown in FIG. 1.

Referring to FIG. 1, the test system 100 generally comprises a memory device 100 undergoing test and a test device 120. As is conventionally understood, the memory device 110 includes a memory cell array 111 and a data I/O (I/O) circuit 112. These two elements may have many different structures depending on the nature of the memory device under test.

The test device 120 generally comprises a test pattern generator 121, a comparator 122, and a test controller 123.

It is assumed in the illustrated embodiment of FIG. 1 that the memory device 110 is a flash memory device. As noted above, flash memory is nonvolatile memories capable of retaining stored data in the absence of applied power. Owing to this ability, flash memory is widely used to store code data (e.g., operating system code) which must be retained during periods when power is not applied.

Given the rapid data access and low current consumption capabilities afforded by flash memory, it is commonly used in mobile electronic devices, such as cellular phones, personal digital assistants (PDA), digital cameras, portable gaming consoles, MP3 players, etc. However, flash memory is also used quite widely in certain home appliances, such as high-definition televisions, digital versatile disks (DVD), routers, global positioning systems (GPS), etc. These noted commercial advantages notwithstanding, embodiments of the present invention may include other types of memory, including but not limited to, mask ROM, programmable ROM, and ferroelectric RAM.

Returning to FIG. 1, the memory cell array 111 is assumed to be configured into a plurality of memory banks. Each bank may be further configured into a plurality of memory or data sectors. Each sector comprises a plurality of memory cells arranged (e.g.,) in a matrix of rows (word lines) and columns (bit lines). Each memory cell may be a single bit memory cell storing 1 bit of data or a multi-bit memory cell storing N-bit data, where N is a natural number greater than 1.

An exemplary plurality of memory cells included in the memory cell array 111 is shown in FIG. 2 under an assumption that memory device 110 is NOR-type flash memory. While this assumption is used below to described the illustrated embodiment, those skilled in the art will recognize that the test system 100 may be used in conjunction with the testing of a flash memory device having a charge storage layer formed from a conductive floating gate or a charge-trap flash (CTF) memory device having a charge storage layer formed from an insulation (or dielectric) film. It is further assumed that the exemplary NOR flash memory performs erase operations on a sector by sector basis, but performs programming operations on a word by word or byte by byte basis.

In the hot-electron channel injection mode used to program the NOR flash memory, a program current is required that is larger by some predetermined amount in view of the high voltage (e.g., 4V to 6V) applied to the constituent drain regions of selected memory cells within memory cell array 111. Accordingly, during a programming operation for the NOR flash memory cells, the number of memory cells that may be simultaneously programmed is conventionally restricted to 2 or 4. For instance, when the number of simultaneously programmable data bits is 4, 16-bit data must be programmed through four (4) programming cycles once the 16-bit data is divided into 4 groups of 4 bits. It should be noted at this point that it is permissible to modify the number of simultaneously programmable data bits in accordance with the structural pattern of a particular memory circuit under test.

In FIG. 1, the data I/O circuit 112 is connected to a data “write-in path” 101 adapted for use in the writing of data to the memory cell array 111. The data I/O circuit 112 is also connected to a data “read-out path” 102 adapted for use in the reading of data from the memory cell array 111. Before writing test pattern data to memory cell array 111 via the data write-in path 101 during a test mode, the data I/O circuit 112 will first store (or retain) the test pattern data. The data I/O circuit 112 is thus able to output the stored test pattern data via the data read-out path 102.

The test pattern generator 121 may be used to generate test pattern data and provide the test pattern data to the data I/O circuit 112 via the data write-in path 101.

The comparator 122 may be used to compare “output test data” provided by the data I/O circuit 112 with the test pattern data (e.g., the output test data returned from memory cell array 111 and/or from the data I/O circuit 112 following the transfer and storage of the test pattern data within memory cell array 111 and/or from the data I/O circuit 112). Based on the comparison result, an error detection signal may be generated indicating that output test data matches (or fails to match) the test pattern data. If the output test data returned from the data I/O circuit 112 matches with the test pattern data, then the error detection signal is indicated as negative (e.g., is disabled). A negative error detection signal indicates that no defect is apparent in the data write-in path 101 and the data read-out path 102 connecting the memory device 110 with the test device 120.

In contrast, if the output test data returned from the data I/O circuit 112 does not match with the test pattern data, a positive error detection signal is provided by comparator 122. A positive error detection signal indicates that at least one defect is apparent in either the data write-in path 101 or the data read-out path 102 connecting the memory device 110 with the test device 120. In certain embodiments of the invention, it is then determined whether the defect(s) are apparent in the data write-in path 101 or the data read-out path 102.

The test controller 123 is configured to control the overall operation of the test device 120. While the test device 120 is operating in the test mode, the test pattern generator 121 generates and provides the test pattern data under the control of the test controller 123. In certain embodiments of the invention, the test controller 123 may be configured to communicate with a constituent control circuit (not shown) within memory device 110 that is configured to control the exchange of data to/from the data I/O circuit 112. In other embodiments of the invention, the test controller 123 may be configured to directly control the data I/O circuit 112.

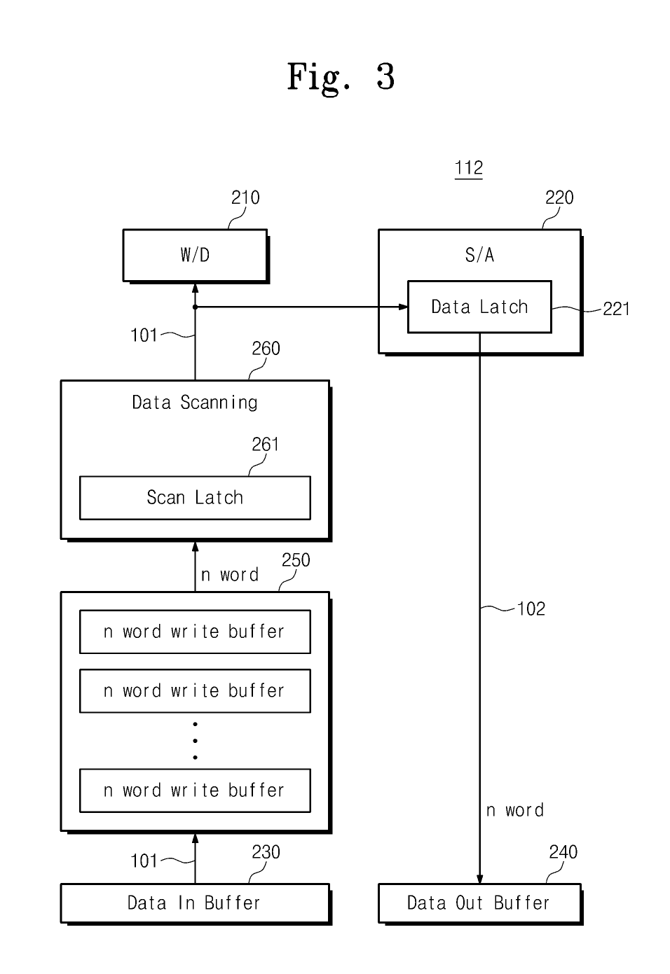

FIG. 3 is a block diagram of the data I/O circuit 112 shown in FIG. 1.

Referring to FIG. 3, the data I/O circuit 112 comprises a writing driver (W/D) 210, a sense amplifier (S/A) 220, a data input buffer 230, a data output buffer 240, a writing buffer 250, and a data scanning circuit 260. The data I/O circuit 112 shown in FIG. 3 is exemplary of a class of circuits adapted for use in a buffer programming scheme.

The writing driver 210 is disposed on the data write-in path 101, and is adapted to apply “write data” to the memory cell array 111 as received from the data write-in path 101 during a programming operation. The writing driver 210 activates bit lines with a bit line voltage in accordance with the write data to be programmed during the programming operation. For instance, if the write data is to be normally programmed (hereinafter, ‘program write data’), the writing driver 210 activates a selected bit line with the bit line voltage. However, if the write data is to be program inhibited (hereinafter, referred to as ‘program-inhibited write data’), the writing driver 210 sets a selected bit line to a predetermined voltage (e.g., the ground voltage) less than the bit line voltage.

The sense amplifier 220 is disposed on the data read-out path 102, and adapted to provide read data from the memory cell array 111 to the data read-out path 102 during a read operation. The sense amplifier 220 detects data bits from memory cells of selected word and bit lines. The data bits read by the sense amplifier 220 may be provided to external circuits via the data output buffer 240. In certain embodiments of the invention, read data may be provided following a pass/fail check performed by a conventionally understood circuit (not shown) in accordance certain operating modes. For example, read data provided by the sense amplifier 220 during a normal read operation may be provided to a memory controller or host.

The sense amplifier 220 comprises a data latch circuit 221. The data latch circuit 221 is connected to the data write-in path 101 extending from the writing driver 210 and data scanning circuit 260. During a test mode and before writing the received write data to memory cell array 111, the data latch circuit 221 latches (or retains) a copy of the write data provided via the write-in path 101. With this configuration, the data latch circuit 221 is able to latch write data on a unit by unit basis (e.g., on an N data words for N data words basis, where N is an integer larger than 1). The latched write data may then be provided to the data read-out path 102.

The data input buffer 230 is disposed on the data write-in path 101 to facilitate the transfer of externally applied write data (e.g., test pattern data) into the writing buffer 250. Thus, the data input buffer 230 may be configured to transfer write data into the writing buffer 250 on a defined data unit by data unit basis (e.g., on a one word by one word basis).

The data output buffer 240 is disposed on the data read-out path 102, and is configured to transfer read data via the data read-out path 102 to one or more external circuit(s), as provided by the data latch circuit 221. Thus, the data output buffer 240 may be configured to transfer read data on a defined data unit basis (e.g., on a one word by one word basis).

Within this configuration, the writing buffer 250 may be loaded with test pattern data, as transferred by the data input buffer 230 via the data write-in path 101. In certain embodiments of the invention, the writing buffer 250 will be configured to store data using a unit basis larger than that compatible with the data scanning circuit 260 (e.g., N data words). Accordingly, the data scanning circuit 260 may be configured to incorporate a scan latch 261 receiving test data from the writing buffer 250. Received write data (e.g., test pattern data) stored in the writing buffer 250 is transferred to the data scanning circuit 260 via scan latch 261. That is, scanning-unit write data from the writing buffer 250, possibly having a first write data size (e.g., N data words), can be sequentially transferred into the data scanning circuit 260, where data scanning circuit 260 is compatible with a second write data size (e.g., M data words, where M is less than or greater than N).

The data scanning circuit 260 receives the scanning-unit write data from the writing buffer 250 and sequentially scans its constituent data bits in order to place the write data in a form compatible with practical programming, or so-called ‘program-compatible write data”, i.e., ‘0’ for single level memory cells (SLC) or ‘10’, ‘01’, and ‘00’ for 2-bit multi-level memory cells (MLC), etc. In order to accomplish this function, the data scanning circuit 260 includes the scan latch 261. The data scanning circuit 260 scans write data loaded to the scan latch 261, and then transfers the write data in program-compatible write data blocks to the writing driver 210.

Then, the writing driver 210 operates to drive bit lines within the memory cell array 111 such that constituent memory cells are programmed using an appropriate number of simultaneously programmed data bits during a programming operation. However, during a test mode, the data scanning circuit 260 scans the write data loaded to the scanning latch 261 and transfers the wrote data in program-compatible write data blocks to the data latch circuit 221.

With this structural configuration, the test pattern data applied via the data write-in path 101 through the data input buffer 230 is received at the data latch circuit 221 before being written to the memory cell array 111. Further, the write data latched by data latch 221 may be provided to the test device 120 via the data read-out path 102 through the data output buffer 240.

In this manner, if the data latch circuit 221 holds the scanning-unit data (i.e., N data words), the comparator 122 is able to compare the test pattern data with the corresponding scanning-unit data (i.e., N data words) as transferred via the data write-in path 101. If the data output buffer 240 receives the scanning-unit data from the data latch circuit 221 and provides the test device 120 with this data using a unit data smaller than N data words (hereinafter, referred to as ‘parcel unit’), the comparison operation between the parcel unit data and the test pattern data may be repeated until a full block (N data words) of the scanning-unit data is subject to comparison. For instance, if the scanning-unit data size is 8 words and a corresponding parcel unit size is one word, a sequence of eight data transfer cycles may be performed before the comparison operation proceeds. Alternately, eight, one word comparison operations may be performed.

While the aforementioned embodiment is illustrative of a data I/O circuit and its operation during a buffer program mode of operation, the present invention is not restrictive to only the foregoing details.

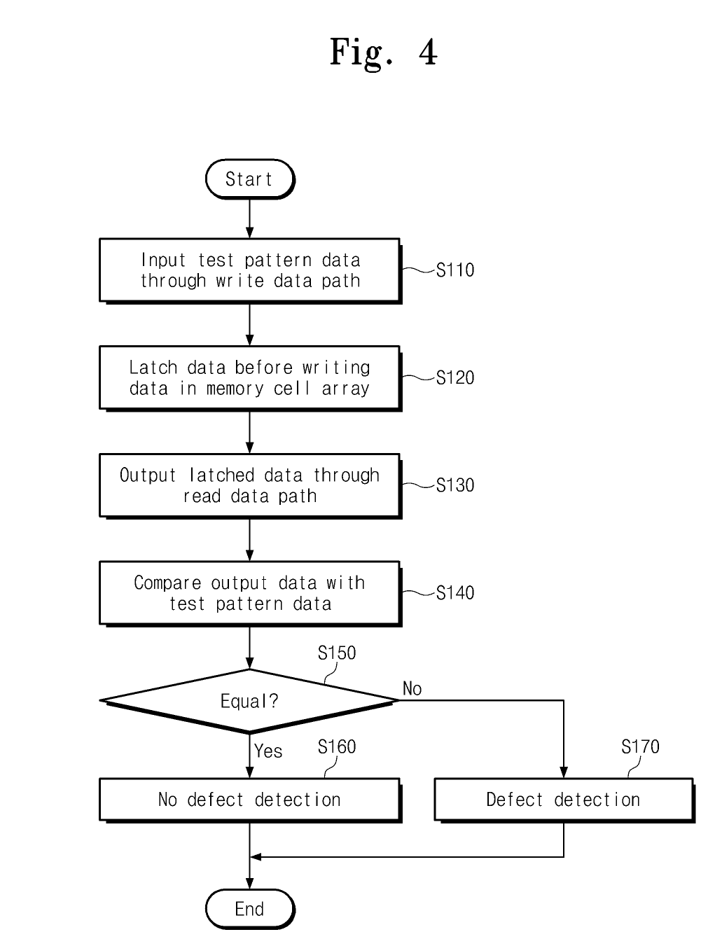

FIG. 4 is a flow chart summarizing a test method for the memory device 110 in accordance with an embodiment of the invention.

In the test mode, the (original) test pattern data provided from the test pattern generator 121 is applied to memory device 100 via the data write-in path 101 (S110).

The test pattern data (now write data) applied via the data write-in path 101 is ultimately latched in the data latch circuit 221 before being written to the memory cell array 111 (S120).

The write data held in the data latch circuit 221 is now provided to the comparator 122 via the data read-out path 102 as output test data (S130).

The comparator 122 operates to compare the output test data with the test pattern data (S140, S150). From the comparison results, if the output test data agrees with the test pattern data, a negative error detection signal is generated. That is, it is determined that there is no defect apparent in the data path (i.e., the data write-in path 101 or the data read-out path 102) of the memory device 110 (S160). In contrast, if the output test data does not agree with the test data, a positive error detection signal is generated. That is, it determined that there is at least one defect in the data write-in path 101 or the data read-out path 102 of the memory device 110 (S170).

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A test system comprising:
a memory device having a data input/output (I/O) circuit configured to connect a data write-in path used to write data to a memory cell array and a data read-out path used to read data from the memory cell array, and further configured during a test mode to retain a copy of test pattern data received in the I/O circuit via the data write-in path as output test data before the test pattern data is stored in the memory cell array as write data; and
a test device configured during the test mode to generate the test pattern data, receive the output test data from the memory device, compare the output test data with the test pattern data, and generate an error detection signal on the basis of the comparison of the output test data and the test data pattern, wherein the error detection signal indicates the presence or absence of a defect in the data write-in or read-out path.

2. The test system of claim 1, wherein the test device comprises:
a test pattern generator generating the test pattern data;
a comparator comparing the output test data with the test pattern data and generating the error detection signal; and
a test controller configured to control the generation of the test pattern data, the application of the test pattern data to the data write-in path, and the comparison of the output test data with the test pattern data.

3. The test system of claim 1, wherein the data I/O circuit comprises:
a data latch circuit retaining the copy of the test pattern data as received via the data write-in path, wherein the data latch retains the copy of the test pattern data before the test pattern data is written to the memory cell array.

4. The test system of claim 3, wherein the data I/O circuit further comprises:
a writing driver disposed on the data write-in path and configured to receive the test pattern data as write data via the write-in path, pass the write data to the data latch, and drive the write data to the memory cell array during a program operation.

5. The test system of claim 4, wherein the data I/O circuit further comprises:
a data output buffer circuit disposed on the data read-out path and configured to receive the output test data from the data latch.

6. The test system of claim 4, wherein the data I/O circuit further comprises:
a data input buffer disposed on the data write-in path and configured to receive the test data pattern from the test device.

7. The test system of claim 6, wherein the data I/O circuit further comprises:
a writing buffer disposed on the data write-in path and configured to receive the test pattern data from the data input buffer, and store the test pattern data as write data in accordance with a defined scanning-unit data size of “N” data words, where N is an integer greater than 1; and
a data scanning circuit disposed on the data write-in path and configured to receive the write data as scanning-unit data having the scanning-unit data size and provide the write data to the writing driver.

8. The test system of claim 7, wherein data scanning unit comprises a scan latch configured to receive the scanning-unit data and convert the scanning-unit data to parcel unit data having a parcel unit data size of “M” data words, where M is less than the N.

9. A test method for a memory device having a memory cell array, the method comprising:
generating test pattern data in a test device connected to the memory device;
applying the test pattern data to the memory device via a data write-in path;
converting the test pattern data into output test data and latching the output test data in an input/output (I/O) circuit of the memory device before writing the test pattern data to the memory cell array;
providing the output test data via a data read-out path of the memory device; and
comparing the output test data with the test pattern data to identify the presence or absence of a defect in the data write-in path or the data read-out path.

10. The method of claim 9, wherein the comparison of the output test data and the test pattern data is performed in the test device.

11. The method of claim 9, which further comprises:
storing the test pattern data as write data in accordance with a scanning-unit data size of “N” data words, where N is an integer greater than 1; and
driving the write data to the memory cell array during a program operation.

12. The method of claim 11, wherein storing the test pattern data comprises latching the test pattern data in a scanning unit having a scan latch.
